(19) United States
(12) Patent Application Publication
(10) Pub. No.: US 2018/0076323 A1
(43) Pub. Date: Mar. 15, 2018

(54) METHOD FOR OPERATION OF A FIELD EFFECT TRANSISTOR ARRANGEMENT

(71) Applicant: TECHNISCHE UNIVERSITÄT DARMSTADT, Darmstadt (DE)

(72) Inventors: Udo SCHWALKE, Munster (DE); Frank WESSELY, Dieburg (DE); Tillmann KRAUSS, Heusenstamm (DE)

(73) Assignee: TECHNISCHE UNIVERSITAT DARMSTADT, Darmstadt (DE)

(21) Appl. No.: 15/809,245

(22) Filed: Nov. 10, 2017

Related U.S. Application Data
(63) Continuation of application No. 14/900,704, filed on Mar. 25, 2016, now abandoned.

(30) Foreign Application Priority Data
Jun. 26, 2013 (DE) 10 2013 106 729.8

(51) Int. Cl. H01L 29/78; H01L 29/40; H01L 29/06; H01L 29/786

(52) U.S. Cl. CPC H01L 29/7838; H01L 29/404; H01L 29/0649; H01L 29/78654; H01L 29/78648; H01L 29/78645; H01L 29/7839

(57) ABSTRACT

A method is provided for operation a field effect transistor arrangement, the field effect transistor arrangement having a planar channel layer including a semiconductor material, a whole surface of an underside of the planar channel layer being applied to a top side of an electrically insulating substrate layer and an upper side of the planar channel layer being covered by an electrically insulating electrode insulation layer, the arrangement having a source electrode disposed by a first side edge of the planar channel layer and having a drain electrode disposed by a second side edge of the planar channel layer, and having a control electrode arranged above the planar channel layer between the source electrode and the drain electrode, wherein an adjusting electrode is arranged on an underside of the substrate layer, and a first contact region between the source electrode and the planar channel layer and a second contact region between the drain electrode and the planar channel layer are each a Schottky barrier, wherein a respective barrier control electrode is arranged between the first contact region of the source electrode and the control electrode and between the second contact region of the drain electrode and the control electrode, the method including providing a first electric potential to the control electrode, providing a second electric potential to the barrier electrodes, and providing a third electric potential to the adjusting electrode.

### BACKGROUND AND SUMMARY

The present application is a continuation of U.S. application Ser. No. 14/900,704, filed Dec. 22, 2015, which is the U.S. national stage of PCT/EP2014/063459, tiled Jun. 25, 2014, which claims priorirty to DE 10 2013 106 729.8, filed Jun. 26, 2013, all of which are incorporated by reference.

The invention relates to a field effect transistor arrangement having a planar channel layer consisting of or comprising a semiconductor material, the whole surface of the underside of said layer being applied to an upper side of an electrically insulating substrate layer, and the upper side of said planar channel layer being covered by an electrically insulating electrode insulation layer, said arrangement also having a source electrode on a first side edge of the channel layer and a drain electrode on a second side edge of the channel layer, and having a control electrode arranged above the channel layer between the source electrode and the drain electrode.

Field effect transistors form the basis for electronic circuits, such as those used in integrated circuits and/or microprocessors, for example. A very large number of field effect transistors are arranged within a space of a few square millimeters, and are contacted with one another in a suitable manner to produce complex circuits. To allow increasing numbers of transistors to be arranged in the smallest possible space, the dimensions of individual transistors are increasingly being reduced and frequently are less than 100 nm2.

Producing complex circuits using such small transistors is costly and prone to errors. Changing the switching states of individual transistors requires energy, which is also convened to heat. Even if the switching state of a transistor is not changed, the leakage currents, which are nearly unavoidable particularly with small dimensions, generate power losses and heat that must be dissipated to keep the field effect transistors twin overheating.

Several variants of field effect transistors have been developed, which differ in terms of their structural configuration and their characteristics. The various transistors may be classified as p-channel transistors, in which defect electrons are used as majority charge carriers, or as n-channel transistors, in which electrons are used as majority charge carriers. Based on the respective type of field effect transistor, a suitably doped semiconductor material is used for the electrically conductive channel layer, in order to provide a sufficient, and optionally the highest possible concentration of majority charge carriers in the channel layer.

Frequently, CMOS technology is used for producing integrated circuits. In this technology, p-channel field effect transistors and n-channel field effect transistors are interconnected and combined with one another in such a way that, when a control voltage is applied to two complementary transistor networks, one transistor network acts as a block and the other is conductive. However, for CMOS technology, twice as many transistors must be provided as would be necessary for producing a corresponding circuit using only one type of field effect transistor, for example in NMOS logic.

With some known field effect transistor arrangements, their characteristics, for example the majority charge carrier type, can be influenced even after the field effect transistor arrangement has been produced. Ambipolar field effect transistors are known from practice, in which the current of the transistor that is available for applications can be generated and sustained both by electrons and by defect electrons. Recent developments along these lines relate, for example, to finFETs or “nanowire” structures, in which the charge carrier channel extends substantially unidimensionally in one direction and the control electrode encompasses the charge carrier channel on as many sides as possible. The substantially unidimensional configuration of the charge carrier channel and the small dimensions thereof allow rapid switching times and low power losses during switching processes to be achieved. However producing such field effect transistor arrangements is highly complex and costly.

It is therefore desirable to configure a field effect transistor arrangement of the type described in the introductory part such that the field effect transistor arrangement has the most advantageous characteristics possible, and at the same time can be cost electively produced.

According to an aspect of the invention an adjusting electrode is arranged on an underside of the substrate layer and in that a contact region between the source electrode and the planar channel layer and a contact region between the drain electrode and the planar channel layer are each embodied as a midgap Schottky barrier. A field effect transistor arrangement of this type can be produced in a small, number of process steps using silicon technology, which has already been widely field-tested and is cost-efficient. As with MISFETs and MOSFETs, which are known from practice, the charge carrier channel is embodied as a planar structure, the thickness of which is substantially narrower than its dimensions in the other two spatial directions, which coextend with the primary plane of the electrically insulating substrate layer on which the planar channel layer is arranged.

The thickness of the planar channel layer may be less than 100 nm or even less than 20 nm, for example, whereas the planar channel layer can extend much farther than 100 nm in the other two spatial directions, and has dimensions of 200×200 nm or 400×400 nm, for example.

The planar channel layer expediently consists of or comprises an undoped semiconductor material. By predetermining an electric potential via the adjusting electrode on the underside of the substrate layer, majority charge carriers can be made to collect within the channel layer, the charge type and/or polarity of which can be predetermined by an electric potential applied at the adjusting electrode. For example, if a negative potential of several volts is generated at the adjusting electrode, electron defects and/or defect electrons or p-holes will form in the planar channel layer, which as majority charge carriers will enable a flow of current between the source electrode and the drain electrode. In contrast, if a positive potential of several volts is applied to the adjusting electrode, electrons will accumulate in the planar channel layer, which as majority charge carriers enable a flow of current between the source electrode and the drain electrode.

Tests have shown that the concentration of majority charge carriers in the planar channel layer is greatest in the region of a boundary surface with the substrate layer on the underside of the planar channel layer, since this region can be most strongly influenced by the electric potential from the adjusting electrode. Although the majority charge carriers form a conducting channel that extends spatially within the planar channel layer in a region facing away from the control electrode, with a suitable configuration and actuation of the control electrode combined with a sufficiently narrow thickness of the planar channel layer, the flow of current through the planar channel layer enabled by a difference in potential between the source electrode and the drain electrode can be influenced and modulated on the underside of the planar channel layer.

Configuring each of the contact regions between the planar channel layer and the source electrode and between the planar channel layer and the drain electrode as a midgap Schottky barrier enables both electrons and electron defects to overcome the midgap Schottky barrier, for example by field emission, and at a sufficiently high temperature by thermionic field emission, and to accumulate in the planar channel layer. One example of a material suitable for producing the midgap Schottky barrier is nickel silicide. The work function difference of the material of the respective contact regions between the source electrode and drain electrode and the planar channel layer is expediently chosen such that the probability of transfer of electrons and defect electrons can be altered, or increased, in similar orders of magnitude by corresponding potentials at the control electrodes.

The thickness of the planar channel layer must be designed as sufficiently narrow to allow an electric field proceeding from the control electrode and extending from the upper side of the planar channel layer to its underside, where the concentration of majority charge carriers is greatest, to build up by means of the control electrode. It has been found that, for example for an exhaustively tested configuration of a field effect transistor arrangement according to the invention in which the planar channel layer has a thickness of approximately 20 nm, a potential difference of 3 volt (an electric potential of −1.5 volt at the adjusting electrode and an electric potential of +1.5 volt at the control electrode) is sufficient to interrupt an electron defect concentration that is sufficient for conducting current in the region of the control electrode, and to displace the electron defects from a region around the control electrode, so that the field effect transistor arrangement will not permit a flow of current from the source electrode to the drain electrode with a potential difference between these electrodes of 0.1 volt. The distance between the source electrode and the drain electrode should be minimized, in view of a desirably low channel resistance or series resistance, for example, or in view of desirably short switching times, and for example should be less than several 100 nm, preferably less than 100 nm. The above-stated potential values were established and confirmed with a field effect transistor arrangement in which the insulation layer of the control electrode has a thickness of 10′ nm and a relative permittivity of 8, and the insulation layer of the adjusting electrode has a thickness of 20 nm and a relative permittivity of 3.9. The source electrode is spaced a distance of 500 nm from the drain electrode and the control electrode extends 200 nm in this direction.

If, in contrast, a lower positive potential or a negative potential is applied to the control electrode, an electric field of sufficient strength will not form in the region of the control electrode, so that the weak electric field will be unable to completely displace the electron defects concentrated on the underside of the planar channel layer, and a continuous conducting channel in the planar channel layer, formed by the electron defects, will enable a flow of current from the source electrode to the drain electrode.

it is preferably provided that a barrier control electrode is arranged in the vicinity of the contact region of the source electrode and in the vicinity of the contact region of the drain electrode. The barrier control electrodes can be used to determine an electric potential in the region of the midgap Schottky barrier and/or to superimpose the Schottky barrier with an electric field, thereby altering the probability that either electrons or electron defects will overcome the Schottky barrier. Thus by applying a suitable electric potential to the barrier control electrodes, the barrier effect of the Schottky barrier for electrons can be reduced, allowing electrons to overcome the Schottky barrier by field emission. If an opposite electric potential is generated via the barrier control electrodes, electron defects will be encouraged, which can then more easily penetrate the Schottky barrier.

It is possible to preset an identical or at least very similar potential for both the adjusting electrode and the barrier control electrodes in order to generate a high concentration of the desired majority charge carriers in the planar channel layer. By presetting electric potentials or electric voltages that are different from one another, characteristics of the field effect transistor arrangement that are dependent on these can be selectively influenced.

To intensify the effects of the barrier control electrodes on the assigned contact regions and/or on the respective Schottky barrier, each of the barrier control electrodes is provided with a section that projects outward in the direction of the planar channel layer. With these outward projecting sections, the barrier control electrodes protrude toward the contact regions of the source electrode and the drain electrode that border the planar channel layer laterally. The resulting decreased distance between the barrier control electrodes and the Schottky barriers causes a potential that, is preset via the barrier control electrodes and/or an electric field induced by the barrier control electrodes to have a greater effect on the Schottky barriers.

According to one embodiment of the concept of the invention, it is provided that the substrate layer consists of or comprises a dielectric material and that a region of the dielectric material that borders the contact region of the source electrode and the contact region of the drain electrode in each case has increased permittivity. The increased permittivity intensifies the effects of the electric field generated by the adjusting electrode in the electrically insulating substrate layer on the Schottky barriers. Since the increased permittivity is restricted spatially to the regions of the dielectric material that border the Schottky barriers, and since the dielectric material does not have increased permittivity particularly in a region in the vicinity of the control electrode, the threshold voltage of the field effect transistor arrangement remains substantially unchanged dependent on the actuation of the control electrode.

The arrangement and the configuration of barrier control electrodes and the increased permittivity of the first electrically insulating material layer in the regions that border the Schottky barrier allow the flow of current and/or the maximum flow of current that can be generated with a predetermined potential difference between the source electrode and the drain electrode to be influenced, without appreciably changing other relevant characteristics of the field effect transistor arrangement at the same time.

To improve the effects of the control electrode, it is provided according to one embodiment of the concept of the invention that the planar channel layer has a narrower thickness in a region around the control electrode than in adjacent regions that are spaced from the control electrode.

It is likewise possible for the electrode insulation layer to have a narrower thickness in a region around the control electrode than in adjacent regions that are spaced from the control electrode.

In both cases, the distance between the control electrode and the underside of the planar channel layer is altered and/or reduced by a suitable configuration of the planar channel layer itself or by a configuration of the electrode insulation layer that electrically insulates the planar channel layer from the control electrode. The majority charge carriers generated via the adjusting, electrode become concentrated on the underside of the planar channel layer. The shorter the distance between the control electrode and the underside of the planar channel layer, the greater the effect of potential differences and of an electric field generated thereby in the area surrounding the control electrode on the majority charge carriers.

According to one embodiment of the concept of the invention, it is provided that the electrode insulation layer has a recess for the control electrode for the purpose of directly contacting the planar channel layer with the control electrode, and that the control electrode is embodied as a metal semiconductor contact. The direct contacting of the planar channel layer with the control electrode allows very short switching times and/or high switching speeds to be achieved. The control electrode acts directly on the planar channel layer and is not separated from the channel layer by the electrode insulation layer or by an electrically insulating material layer. The characteristics of the field effect transistor arrangement can be influenced by suitably specifying the materials and material combinations used for the metal semiconductor contact.

Rather than directly contacting the planar channel layer with the control electrode, the planar channel layer may also be provided with spaced recesses for control electrode arms that protrude from die control electrode and project up to the substrate layer. The control electrode arms that project up to the substrate layer and optionally into the planar channel layer can laterally encompass a region of the planar channel layer that is located between the projecting control electrode arms. This region of the planar channel layer located in each case between two projecting control electrode arms is then nearly completely surrounded on three sides by the control electrode and the respective control electrode arms, so that an electric field generated by the control electrode acts on this channel region over three lateral surfaces, thereby enabling an appreciably improved control of the field effect transistor arrangement. In addition, the control electrode arms can generate an electric field which superimposes the electric field of the adjusting electrode, and the influence of which on the planar channel layer is at least partially compensated for, allowing the conductivity of the conducting channel generated by the adjusting electrode to likewise be influenced very directly and rapidly. The modulation effect of the control electrode enhanced in this manner is particularly suitable for high-temperature applications of the field effect transistor arrangement.

The control electrode can have two different metals or metal layer systems with different work functions, wherein each metal must be in direct contact with the insulating layer in the direction of the planar channel layer. The combination of two metals with different work functions allows the potential differences between the control electrode and the adjusting electrode, which are necessary for generating or blocking a flow of current from the source electrode to the drain electrode based on the majority charge carriers that are determined by the adjusting electrode, to be influenced. Undesirable power losses in CMOS circuits that are produced with the field effect transistor arrangement according to the invention can thereby be reduced.

The field effect transistor arrangement can expediently be produced using the SOI technique known in practice, in which a very thin silicon layer is arranged on a carrier substrate on an electrically insulating material layer. The field effect transistor arrangement according to the invention does not require doping of the semiconductor material or of the planar channel layer, although in individual cases doping may be provided and may be beneficial. Advantageously, the potential difference that is necessary for and/or characteristic of a modulation of the flow of current can be influenced by a doping of the substrate layer. For example, by doping the substrate layer with phosphorous or with boron, the amount of switching voltage required at the control electrode can be decreased to significantly less than 1 volt.

According to the invention, complex circuits can be easily and cost-efficiently produced by arranging a plurality of planar channel layers consisting of or comprising a semiconductor material, each with respectively assigned source electrodes, drain electrodes, control electrodes and adjusting electrodes, side by side on a common carrier substrate and separating them from one another by vertical trenches or insulators. With such an arrangement of a large number of field effect transistors having the above-described features and characteristics, reconfigurable circuits can also be produced, for example, in which a small space requirement can be combined with short switching times and low power losses. Each planar channel layer can be concentrated with electrons or with electron defects as majority charge carriers, depending on the actuation of the assigned adjusting electrode, and can therefore be used as an n-channel transistor or as a p-channel transistor. It is not necessary to provide respective stationary n-channel transistors and p-channel transistors when producing complex circuits.

### BRIEF DESCRIPTION OF THE DRAWINGS

In the following, examples of embodiments of the concept of the invention, which are illustrated in the set of drawings, will be specified in greater detail. The drawings show in:

FIG. 1 a schematic sectional view of a field effect transistor arrangement according to the invention, having a planar channel layer consisting of or comprising a semicontuctor material, and having a source electrode and a drain electrode, and having a control electrode, and also having an adjusting electrode arranged on an opposite side of the planar channel layer.

FIG. 2 a schematic plan view of the field effect transistor arrangement shown FIG. 1,

FIG. 3 a schematic representation of an energy band diagram for the planar channel layer with the field effect transistor arrangement in a blocking state, in which electrons defects have accumulated.

FIG. 4 a schematic representation of an energy band diagram according to FIG. 3, in which electrons have accumulated in the planar channel layer,

FIG. 5 a simulated input characteristic curve with a common actuation and/or uniform determination of the potential of the adjusting electrode and the barrier control electrodes,

FIG. 6 a simulated input characteristic curve based on the actuation of the control electrode for various operating points that are predetermined by the actuation of the adjusting electrode and the harrier control electrodes,

FIG. 7 a schematic sectional view of a field effect transistor arrangement according to FIG. 1 in which the barrier control electrodes have a different configuration,

FIG. 8 a schematic sectional view of a field effect transistor arrangement in which the substrate layer has regions of different permittivity,

FIG. 9 a schematic sectional view of a field effect transistor arrangement having a control electrode that is shifted to an underside of the planar channel layer,

FIG. 10 a schematic sectional view of a field effect transistor arrangement in which the control electrode consists of or comprises two different metals and/or metal layer systems,

FIG. 11 a schematic sectional view of a field effect transistor arrangement in which the control electrode is contacted directly to the planar channel layer,

FIG. 12 a schematic sectional view of a field effect transistor arrangement having a different configuration of the control electrode,

FIG. 13 a sectional view of the field effect transistor arrangement shown in FIG. 12 along the line XII-XII in FIG. 12,

FIG. 14 a schematic sectional view of a field effect transistor arrangement in which a plurality of planar channel layers, each with respectively assigned source electrodes, drain electrodes, control electrodes and adjusting electrodes, are arranged on a common carrier substrate and are separated from on another by a vertical insulation layer, and

FIG. 15 a schematic sectional view of a field effect transistor arrangement, which corresponds largely to the field effect transistor arrangement shown in FIG. 14, wherein in place of the horizontal insulation layer a likewise electrically insulating layer sequence of alternatingly p-doped and n-doped semiconductor material is arranged,

FIG. 16 a schematic sectional view of a field effect transistor arrangement in which no barrier control electrodes are necessary or provided,

FIG. 17 a schematic sectional view of a field effect transistor arrangement, in which the control electrode is arranged eccentrically.

### DETAILED DESCRIPTION

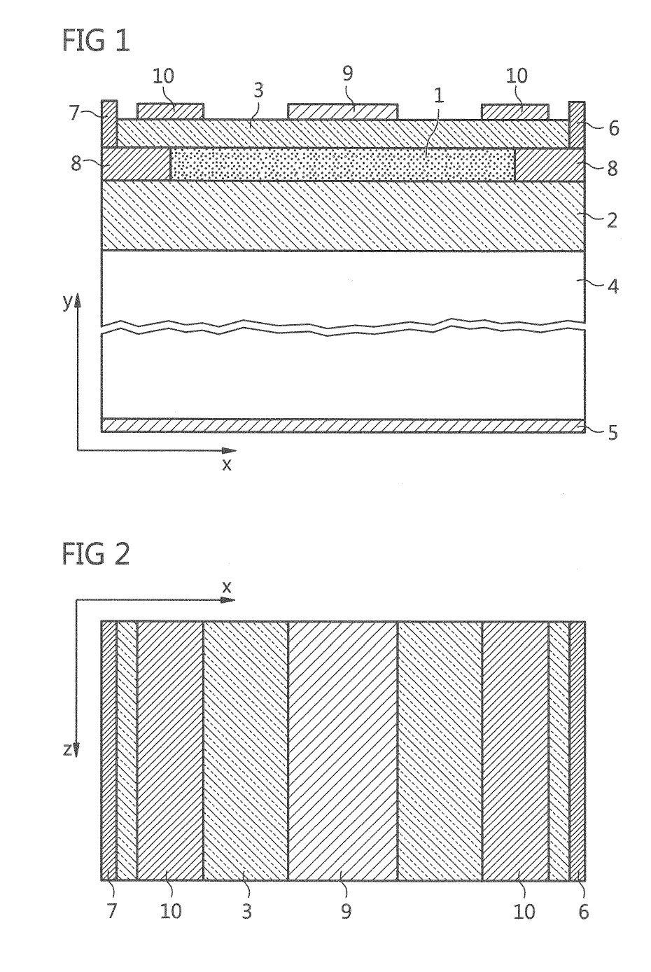

A field effect transistor arrangement schematically illustrated in FIGS. 1 and 2 has a planar channel layer 1 made of an undoped silicon material. The planar channel layer 1 is arranged on an upper side of an electrically insulating substrate layer 2, which consists of or comprises silicon oxide. The planar channel layer 1 is covered by an electrically insulating electrode insulation layer 3, which likewise consists of or comprises silicon oxide. Below substrate layer 2 a carrier substrate 4, and on the entire surface of the underside thereof, an electroconductively contactable adjusting electrode 5 are arranged.

On two opposite side edges of planar channel layer 1, an electroconductively contactable source electrode 6 and a drain electrode 7 are arranged, which protrude through electrode insulation layer 3, each into a contact region 8 that borders the planar channel layer laterally. Contact region 8 is embodied as a midgap Schottky barrier and is produced from nickel silicide.

On an upper side of electrode insulation layer 3, between source electrode 6 and drain electrode 7, a likewise electroconductively contactable control electrode 9 is arranged. Between control electrode 9 and source electrode 6 and between control electrode 9 and drain electrode 7, a respective barrier control electrode 10 is arranged, each barrier control electrode being electroconductively contactable separately from control electrode 9.

Planar channel layer 1 has a thickness (shown in FIGS. 1 and 2 in the y-direction) of approximately 20 nm and an extension of approximately 400 nm in each of the two other spatial directions (shown in FIGS. 1 and 2 as x-direction and z-direction). Source electrode 6, drain electrode 7, control electrode 9 and the two barrier control electrodes 10 have a strip-shaped configuration and each extend in parallel in a direction (shown in FIGS. 1 and 2 as the z-direction) over substantially the entire length of planar channel layer 1. Therefore, the contact regions also extend between source, electrode 6 or drain electrode 7 and the planar channel layer 1 located therebetween, over substantially the entire length of the planar channel layer 1.

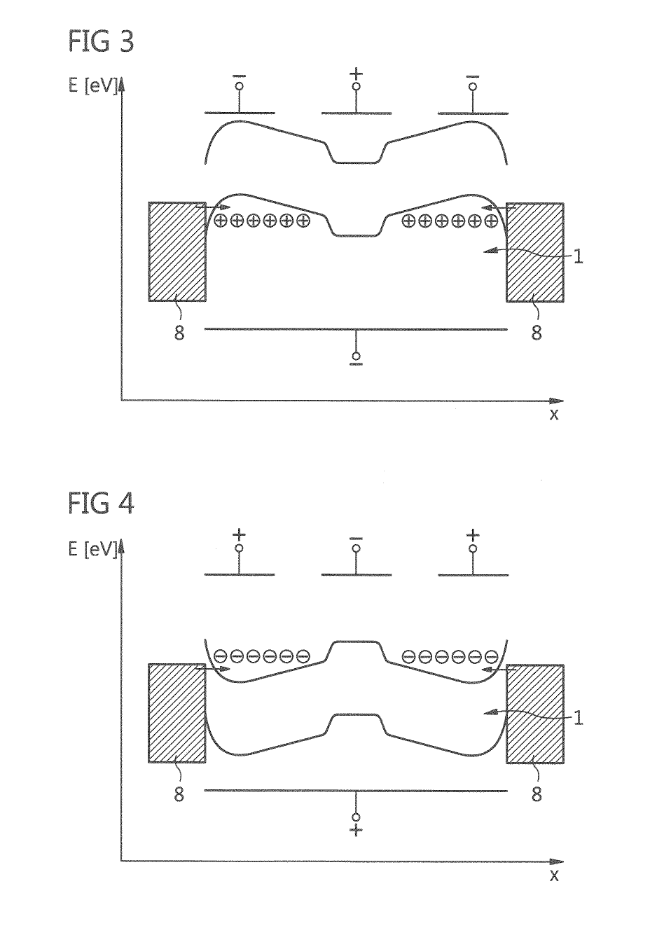

FIGS. 3 and 4 schematically illustrate the curve of the energy bands in the semiconductor material of planar channel layer 1, wherein different potential differences are provided between adjusting electrode 5 and the two barrier control electrodes 10 and between the adjusting electrode and control electrode 9.

In the embodiment shown in FIG. 3, a negative electric potential of approximately −10 volt is applied to adjusting electrode 5 and to the two barrier control electrodes 10, whereas a positive electric potential of approximately +2 volt is present at control electrode 9. As a result of the electric field, generated by adjusting electrode 5 and the two barrier control electrodes 10, electron defects accumulate in the planar channel layer 1 and represent the majority charge carriers in planar channel layer 1. The electrode defects are concentrated primarily on an underside of planar channel layer 1 which faces substrate layer 2, and form a conducting channel that can enable a flow of current between source electrode 6 and drain electrode 7. The greater the negative electric potential of adjusting electrode 5 and of barrier control electrodes 10, the greater the concentration of the electrode defects and therefore the maximum possible flow of current through planar channel layer 1.

At the same time, the electron defects are displaced in a region around control electrode 9 by the electric field generated by control electrode 9. Control electrode 9, which is located on a positive potential, generates an electric field in planar channel layer 1 in an area around control electrode 9 that modulates the flow of current enabled by the electron defects and—with an electric field of sufficient strength—can nearly completely interrupt said flow of current.

In the embodiment shown in FIG. 4, a positive electric potential of approximately +10 volt is applied to adjusting electrode 5 and to the two barrier control electrodes 10, whereas a negative electric potential of approximately −2 volt is present at control electrode 9. In planar channel layer 1, electrons accumulate as majority charge carriers and form a conducting channel on the underside of planar channel layer 1, which is interrupted by the electric field of control electrode 9.

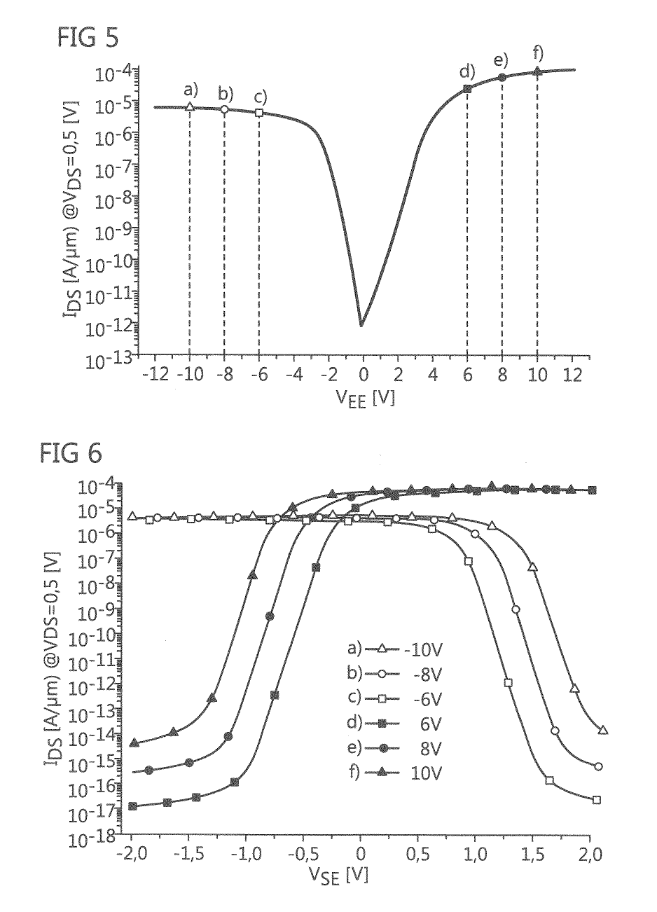

In FIG. 5, for purposes of illustration, a simulated input characteristic curve for the above-described field effect transistor arrangement is shown. Either a negative electric potential (potential values a), b) and e)) or a positive electric potential (potential values d), e) and f)) is preset at, adjusting electrode 5 and at the two barrier control electrodes 10. The flow of current IDS calculated on the basis of the preset electric potential is shown for a voltage VDS, also preset, of 0.5 volt between source electrode 6 and drain electrode 7. If the amount of electric voltage VEE present exceeds several volts, a very substantial flow of current through planar channel layer 1 will occur with both a negative and a positive potential at adjusting electrode 5 and the two barrier control electrodes 10. This shows that applying a positive or negative voltage to adjusting electrode 5 causes majority charge carriers of different polarity to accumulate in planar channel layer 1, but in both cases, a flow of current between source electrode 6 and drain electrode 7 that can be modulated by control electrode 9 can be enabled.

In FIG. 6, for the potential values a) to f) or −10 volt to +10 volt at adjusting electrode 5 and the two barrier control electrodes 10 highlighted in FIG. 5, simulated curves for the flow of current IDS based on a control voltage VSE ranging from −2 volt to +2 volt applied to control electrode 9 are shown. Although the fundamental dependency of the flow of current IDS on the control voltage VSE does not, differ appreciably, for the different potential values a) to f) the change between the non-conductive state and the conductive, state occurs in planar channel layer 1 with slightly different values for the control voltages VSE.

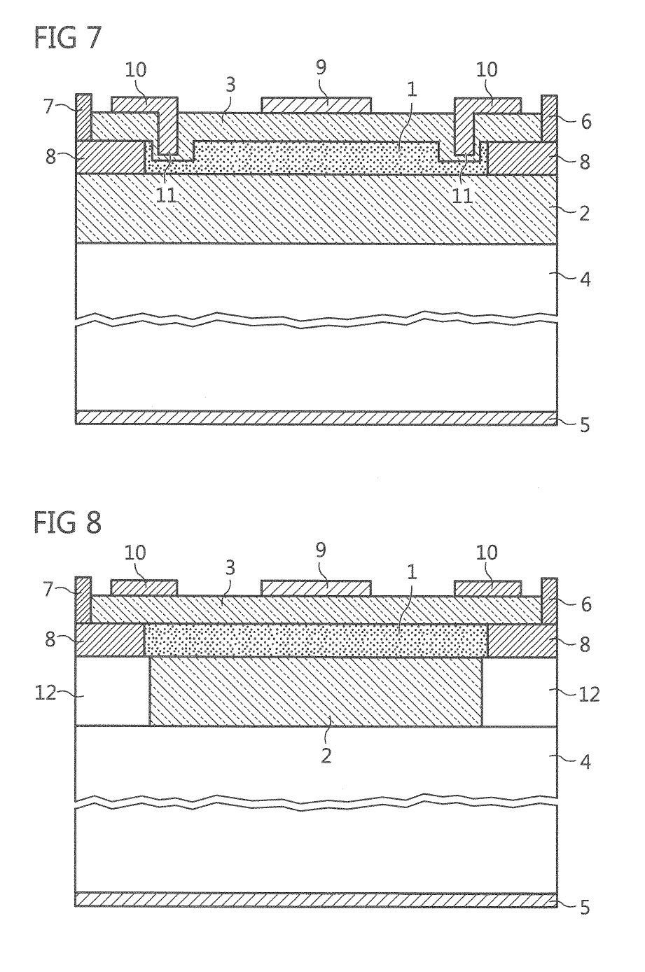

In a differently configured field effect transistor arrangement according to FIG. 7, the barrier control electrodes 10 each have a section 11 that projects outward in the direction of planar channel layer 1, each section extending over the entire length of the strip-shaped barrier control electrodes 10. The projecting sections 11 extend up to the area around the contact regions 8 and are spaced by only a short lateral distance from the contact regions 8. Due to this short distance and the proximity over a large area, the electric field that can be generated with the barrier control electrodes 10 has a much greater effect on the contact regions 8 and/or on the Schottky barriers formed there than the flat barrier control electrodes 10 shown in FIGS. 1 and 2 when a comparable electric potential is present.

FIG. 8 shows a schematic illustration of another differently configured field effect transistor arrangement, in which increased permittivity is present in the substrate layer 2 in two regions 12 that border the contact regions 8 of source electrode 6 and drain electrode 7. The electric field generated by adjusting electrode 5 on the underside of substrate layer 2 therefore has a greater effect on the contact regions 8 than on a center region of planar channel layer 1, between the two contact regions 8 and particularly below control electrode 9.

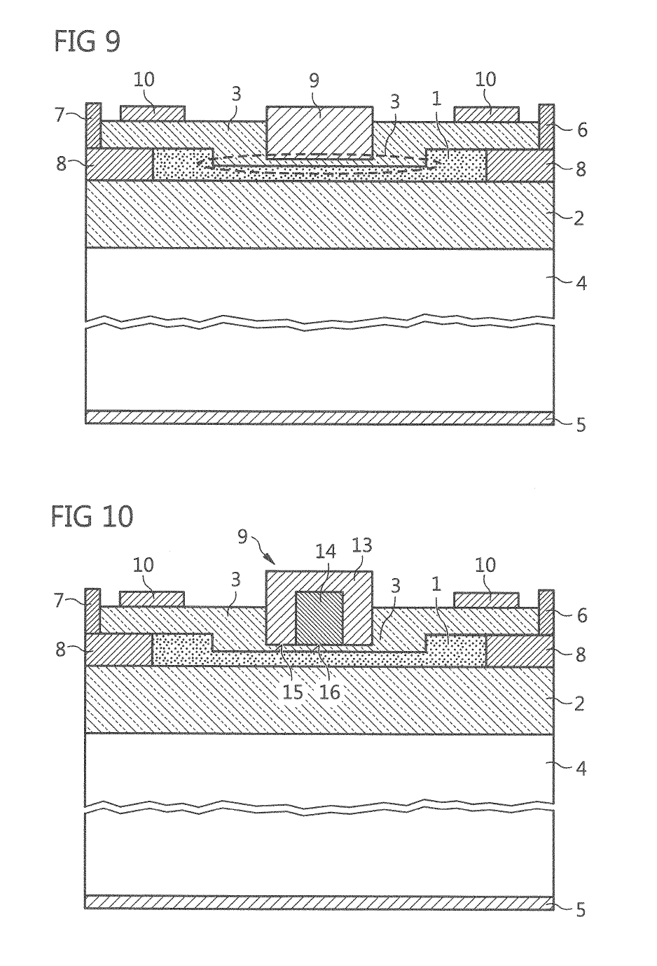

In the embodiment shown schematically in FIG. 9, the distance between control electrode 9 and the underside of planar channel layer 1, which faces away from control electrode 9, is decreased and is shorter than in the field effect transistor arrangements described above. This enables lower control voltages at control electrode 9 and shorter switching times to be realized, in order to modulate and release or completely interrupt the flow of current

According to the embodiment shown by way of example in FIG. 10, control electrode 9 can consist of or comprises two regions 13 and 14 made of different metals or of a metal layer system. The two regions 13 and 14 are separate from one another but are arranged bordering one another, each with one end face 15, 16 facing in the direction of planar channel layer 1 and in direct contact with the electrically insulating electrode insulation layer 3, which separates control electrode 9 from planar channel layer 1. The switching characteristics of control electrode 9 can advantageously be influenced by appropriately selecting and predetermining the relevant electric properties of the metals arranged in the two regions 13 and 14 or in the metal layer system. In particular, the input characteristic curves and therefore the potential values that are necessary for a change in the switching state can also be changed based on the majority charge carriers.

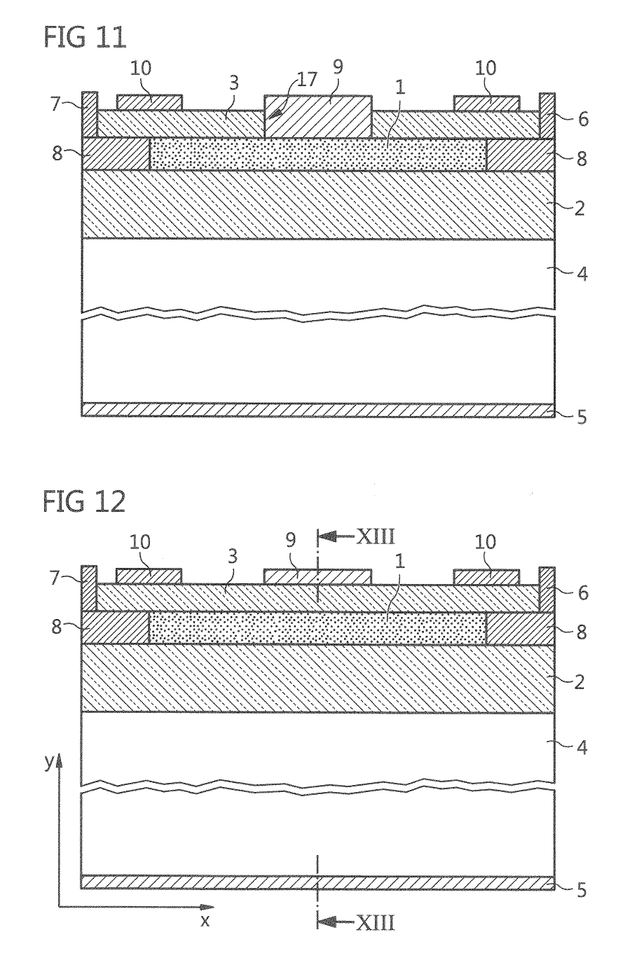

In a field effect transistor arrangement shown in FIG. 11, control electrode 9 is arranged in a recess 17 in electrode insulation layer 3, in direct contact with planar channel layer 1. Control electrode 9 is embodied in this case as a metal semiconductor contact, so that extremely short switching times for actuating the field effect transistor arrangement with control electrode 9 are possible.

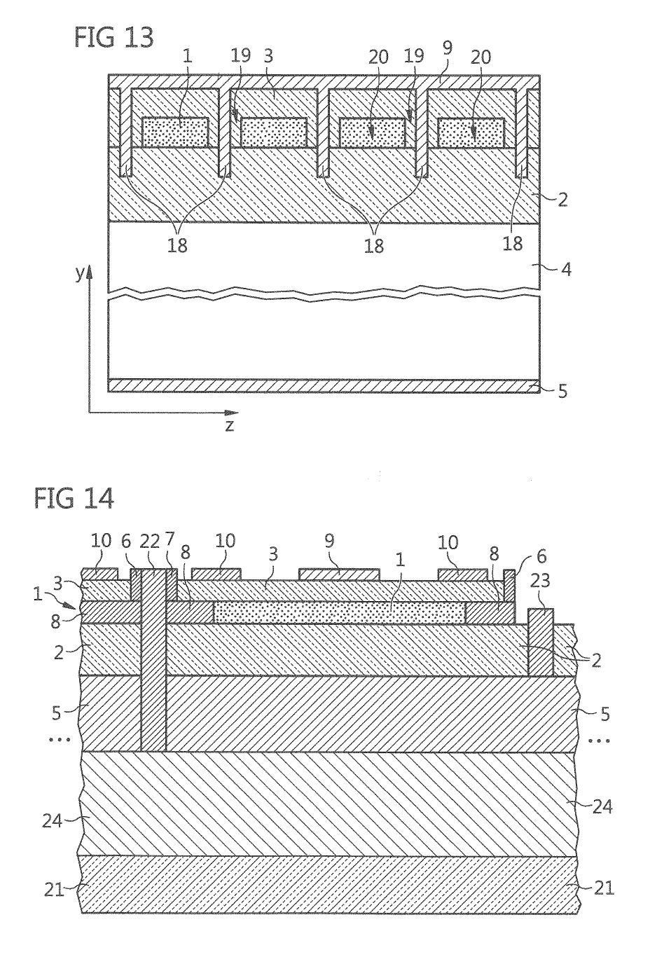

FIGS. 12 and 13 show another different embodiment of a field effect transistor arrangement. Control electrode 9 has control electrode arms 18 angled to the side, each projecting toward substrate layer 2 and extending through recesses 19 in planar channel layer 1 and into substrate layer 2. In the region around control electrode 9, planar channel layer 1 is configured in the form of a strip. A region 20 of channel layer 1 located between two adjacent control electrode arms 18 is encompassed on three lateral surfaces substantially entirely by control electrode 9 and by an electric field generated by control electrode 9, which can act particularly effectively on this region 20 of channel layer 1.

Merely by way of example, FIG. 14 shows an arrangement of a plurality of planar channel layers 1 consisting of or comprising a semiconductor material, each with assigned source electrodes 6, drain electrodes 7, control electrodes 9 and adjusting electrodes 5, arranged side by side on a common carrier substrate 21 and separated from one another by vertical insulators 22. Each planar channel layer 1 is assigned a substrate layer 2, these being likewise separated from one another by the vertical insulators 22, and an adjusting electrode 5 arranged beneath said substrate layer in a planar manner, wherein adjusting electrode 5 can be electroconductively contacted via an adjusting electrode terminal 23 leading to the upper side. Between carrier substrate 21 and the adjusting electrodes 5, an additional horizontal insulating layer 24 is arranged. Each of the field effect transistor arrangements arranged side by side on the common carrier substrate 21 can be actuated by applying a separate adjusting potential and a separate control voltage, independently of the field effect transistor arrangement arranged immediately adjacent to it.

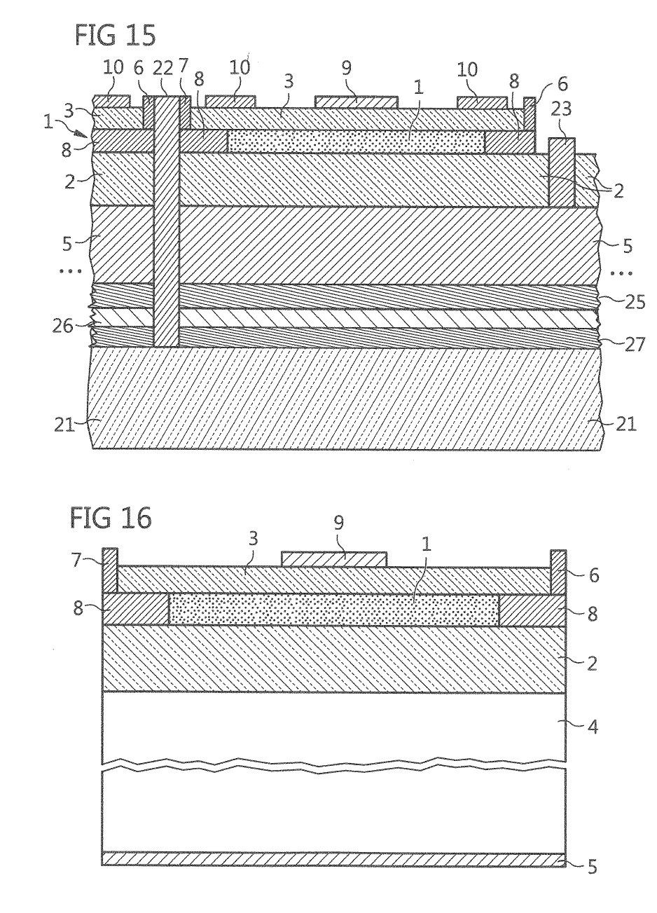

In the embodiment illustrated by way of example in FIG. 15, a field effect transistor arrangement very similar to the variant shown in FIG. 14 is shown. In place of the horizontal insulating layer 24, which can consist, for example, of or comprise silicon dioxide or some other suitably electrically insulating material, in this embodiment a sequence of layers of differently doped semiconductor material is provided, which likewise has an electrically insulating effect and suppresses a flow of current from the adjusting electrodes 5 to carrier substrate 21. In the embodiment example shown, the sequence of layers consists of or comprises a sequence of a p-doped silicon layer 25, an n-doped silicon layer 26 and a p-doped silicon layer 27.

A suitable selection and determination of the materials that are used for planar channel layer 1, for the various electrodes, for the contact regions and for the insulating layers allows the formation and arrangement of barrier control electrodes to be dispensed with. FIG. 16 shows a corresponding configuration of a field effect transistor arrangement without barrier control electrodes, merely by way of example.

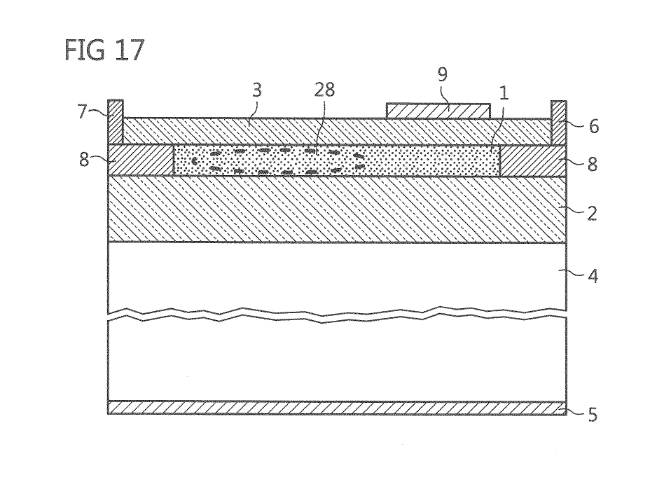

In an embodiment shown by way of example in FIG. 17, control electrode 9 is arranged eccentrically. Control electrode 9 therefore has a first distance from source electrode 6 and a different second distance from drain electrode 7. With an appropriate voltage assignment for the source electrodes 6 and drain electrodes 7 and for the control electrodes 9 and adjusting electrodes 5, this asymmetrical arrangement of control electrode 9 enables the controlled generation of an impact ionization zone 28 between control electrode 9 and the drain electrode 7, which is spaced a greater distance in this embodiment example. This effect increases the slope of the lower threshold characteristic curve of the field effect transistor arrangement when control electrode 9 is actuated and enables the production and operation of energy-saving switching circuits that also respond substantially more quickly than previously known switching circuits. At the same time, the long-term reliability of the field effect transistor arrangement is increased by a spatial separation of control electrode 9 from impact ionization zone 28.

1. A method for operation a field effect transistor arrangement, the field effect transistor arrangement having a planar channel layer comprising a semiconductor material, a whole surface of an underside of the planar channel layer being applied to a top side of an electrically insulating substrate layer and an upper side of the planar channel layer being covered by an electrically insulating electrode insulation layer, the arrangement having a source electrode disposed by a first side edge of the planar channel layer and having a drain electrode disposed by a second side edge of the planar channel layer, and having a control electrode arranged above the planar channel layer between the source electrode and the drain electrode, wherein an adjusting electrode is arranged on an underside of the substrate layer, and a first contact region between the source electrode and the planar channel layer and a second contact region between the drain electrode and the planar channel layer are each a Schottky barrier, wherein a respective barrier control electrode is arranged between the first contact region of the source electrode and the control electrode and between the second contact region of the drain electrode and the control electrode, the method comprising
providing a first electric potential to the control electrode;
providing a second electric potential to the barrier electrodes: and
providing a third electric potential to the adjusting electrode.

2. The method as set forth in claim 1, wherein the first electric potential is different from the second electric potential.

3. The method as set forth in claim wherein the first electric potential is different from the third electric potential.

4. The method as set forth in claim 1, wherein the second electric potential is different from the third electric potential.

5. The method as set forth in claim 2, wherein the second electric potential is a negative electric potential.

6. The method as set forth in claim 4, wherein the second electric potential is a positive electric potential.

7. The method as set forth in claim 3, wherein the third electric potential is a positive electric potential.

8. The method as set forth in claim 4, wherein the third electric potential is a negative electric potential.

9. The method as set forth in claim 1, providing a flow of current between the source electrode and the drain electrode through the planar channel layer and interrupting the flow of current by providing the second electric potential and the third electric potential.

10. The method as set forth in claim 1, providing a flow of current between the source electrode and the drain electrode through the planar channel layer and modulating, the flow of current by providing the first electric potential and the second electric potential.

11. The method as set forth in claim 1, wherein each barrier control electrode has a section that projects outward in a direction of the planar channel layer, the method comprising generating electric fields affecting the first and second contact regions with the barrier control electrodes.

12. The method as set forth in claim 1, wherein the electrically insulating substrate layer comprises a dielectric material, and respective regions of the dielectric material that border the first contact region of the source electrode and the second contact region of the drain electrode each have increased permittivity relative to other regions of the dielectric material, the method comprising generating an electric field by the adjusting electrode that has a greater effect on the first and second contact regions than on a center region of the planar channel region between the first and second contact regions and below the control electrode.

13. The method as set forth in claim 1, comprising providing an electric potential difference between the adjusting electrode and the control electrode wherein the control electrode has two different metals with different work functions.

14. The method as set forth in claim 1, comprising providing an electric potential difference between the adjusting electrode and the control electrode wherein the control electrode has a first distance from the source electrode and a second distance, different from the first distance, from the drain electrode.

15. The method as set forth in claim 1, wherein the planar channel layer comprises a plurality of planar channel layers, each of the plurality of planar channel layers having a respective assigned source electrode, a respective drain electrode, a respective control electrode and a respective adjusting electrode, the plurality of planar channel layers being arranged side by side on a common carrier substrate and being separated from one another by vertical trenches or insulators, the method comprising, for each of the plurality of planar channel layers providing a first electric potential difference between the respective adjusting electrode and respective barrier control electrodes; and
providing a second electric potential difference between the respective adjusting electrode and the respective control electrode.
